(19) United States
(12) Patent Application Publication
(10) Pub. No.: US 2002/0145162 A1
(43) Pub. Date: Oct. 10, 2002

(54) Non-volatile semiconductor storage device and method for producing the same

(75) Inventors: Akihiro Kamada, Osaka (JP); Hiromasa Fujimoto, Kyoto (JP); Kenji Okada, Osaka (JP); Seiki Ogura, Wappingers Falls, NY (US)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.,

(21) Appl. No.: 10/062,521

(22) Filed: Feb. 5, 2002

(30) Foreign Application Priority Data
Apr. 5, 2001 (JP) 2001-107453

(51) Int. Cl. H01L 29/76

(52) U.S. Cl. 257/316; 257/288

(57) ABSTRACT

A non-volatile semiconductor storage device includes a semiconductor substrate provided with a step portion in an upper portion thereof, and having a first region that is an upper level of the step portion and a second region that is a lower level thereof, a control gate electrode formed on the first region of the semiconductor substrate via a gate insulating film, and a floating gate electrode formed on the side face of the control gate electrode on the side of the step portion and on the step portion via an insulating film. The side face of the step portion forms an obtuse angle with respect to the upper surface of the second region, and the insulating film has a substantially uniform thickness on the step portion.

### BACKGROUND OF THE INVENTION

The present invention relates to a non-volatile semiconductor storage device, in particular, a non-volatile semiconductor storage device in which a floating gate electrode is formed on a step portion of a semiconductor substrate, and a method for producing the same.

At present, flash EEPROMs (electrically erasable programmable read only memories) are widely used as non-volatile storage devices on which electrical write and erase can be performed. The cell structure of a memory cell of such a non-volatile semiconductor storage device can be classified roughly into two types. One is a stack gate type having a structure in which a control gate electrode is stacked on a floating gate electrode, and the other is a split gate type having a structure in which both the floating gate electrode and the control gate electrode are opposed to a channel region.

Hereinafter, the split gate type non-volatile semiconductor storage device provided with a step portion below a floating gate electrode in order to improve the write property that is proposed in U.S. Pat. No. 6,051,860 will be described.

FIG. 17 shows a cross-sectional structure of the non-volatile semiconductor storage device disclosed in the above publication. As shown in FIG. 17, a control gate electrode 203 is formed on a region of the upper level of a semiconductor substrate 201 having a step portion 201a in its upper portion via a gate insulating film 202. On the step portion 201a of the semiconductor substrate 201, a floating gate electrode 205 is formed, opposing the side face of the control gate electrode 203 via an insulating film 204. The insulating film 204 serves as a capacitance insulating film in a portion that is opposed to the control gate electrode 203 and serves as a tunnel insulating film in a portion that is opposed to the semiconductor substrate 201.

A source diffusion layer 206 is formed in a region to the side of the gate electrode 203 on the upper level of the semiconductor substrate 201. A low concentration drain diffusion layer 207 is formed in a region below the floating gate electrode 205 on the lower level of the semiconductor substrate 201, and a high concentration drain diffusion layer 208 is formed outside the low concentration drain diffusion layer 207.

However, the conventional non-volatile semiconductor storage device has the insulating film 204 that serves as a tunnel insulating film on the step portion 201a. Therefore, the insulating film 204 is less reliable than a tunnel insulating film formed on a flat substrate in which the step portion 201a is not formed. This is caused for the following reason. When forming a tunnel insulating film on a semiconductor substrate having the step portion 201a by thermal oxidation, a stress due to thermal oxidation is applied to the corners on the upper level and the lower level of the step portion 201a in the tunnel insulating film, so that a film having a uniform thickness cannot be formed. As a result, a stress due to an electric field concentrates in the corners so that the quality of the film is poor.

### SUMMARY OF THE INVENTION

It is an object of the present invention to solve the above-described conventional problem in the non-volatile semiconductor storage devices including a semiconductor substrate having a step portion below a floating gate electrode and to improve the reliability of a tunnel insulating film covering the step portion.

In order to achieve the above object, in the present invention, the angle formed between the side face of the step portion and the surface on the lower level thereof is an obtuse angle, or the present invention has a multilayered structure in which the tunnel insulating film includes a thermal oxide film and a deposited oxide film.

More specifically, a first non-volatile semiconductor storage device of the present invention includes a semiconductor substrate provided with a step portion in an upper portion thereof, and having a first region that is an upper level of the step portion and a second region that is a lower level thereof; a control gate electrode formed on the first region of the semiconductor substrate via a gate insulating film; and a floating gate electrode formed on the side face of the control gate electrode on the side of the step portion and on the step portion via an insulating film. The side face of the step portion forms an obtuse angle with respect to the upper surface of the second region, and the insulating film has a substantially uniform thickness on the step portion.

According to the first non-volatile semiconductor storage device, even if the insulating film is formed by thermal oxidation, a stress applied to the corners on the upper level and the lower level of the step portion in the insulating film is small, so that the thickness of the insulating film can be uniform. Therefore, the reliability of the insulating film serving as the tunnel insulating film is improved because of the uniform quality of the insulating film.

It is preferable that the angle formed between the side face of the step portion and the upper surface of the second region is about 100° or more.

It is preferable that the angle formed between the side face of the step portion and the upper surface of the second region is about 110° or more and about 130° or less. With this, when forming, for example, an n-type drain diffusion layer in the second region, the amount of ions implanted into the side face of the step portion is reduced, which can prevent n-type impurities from suppressing implantation of electrons into the floating gate electrode during a write operation.

In the first non-volatile semiconductor storage device, it is preferable that the insulating film is a thermal oxide film. This embodiment improves the film quality of the insulating film as a tunnel insulating film.

A second non-volatile semiconductor storage device of the present invention includes a semiconductor substrate provided with a step portion in an upper portion thereof, and having a first region that is an upper level of the step portion and a second region that is a lower level thereof; a control gate electrode formed on the first region of the semiconductor substrate via a gate insulating film; and a floating gate electrode formed on a side face of the control gate electrode on a side of the step portion and on the step portion via a first insulating film and a second insulating film provided in this order from the substrate. The second insulating film is formed with a deposited film.

According to the second non-volatile semiconductor storage device, even if the tilt angle of the step portion in the second insulating film formed with a deposited film is small, that is, an angle close to 90°, the thickness in the corners of the step portion is not thin as opposed to a thermal oxide film. Therefore, since the thickness of the second insulating film is uniform, the film quality of the tunnel insulating film including the first and second insulating films is improved.

In the second non-volatile semiconductor storage device, it is preferable that the first insulating film is a thermal oxide film, and the second insulating film is an oxide film. With this, the tunnel insulating film having a multilayered structure can be formed reliably. Moreover, the first insulating film on the substrate side becomes dense, and the thickness of the second insulating film becomes uniform.

In the second non-volatile semiconductor storage device, it is preferable that the first insulating film is a thermal oxide film, and the second insulating film is an oxynitride film. In this embodiment, the second insulating film serving as a capacitance insulating film in a portion that is opposed to the control gate electrode is an oxynitride film, and therefore the charge retention characteristics of the floating gate electrode can be improved.

A third non-volatile semiconductor storage device of the present invention includes a semiconductor substrate provided with a step portion in an upper portion thereof, and having a first region that is an upper level of the step portion and a second region that is a lower level thereof; a control gate electrode formed on the first region of the semiconductor substrate via a gate insulating film; and a floating gate electrode formed on a side face of the control gate electrode on a side of the step portion and on the step portion via a first insulating film, a second insulating film and a third insulating film provided in this order from the substrate. The third insulating film is formed with a deposited film.

According to the third semiconductor storage device, even if the tilt angle of the step portion in the third insulating film formed with a deposited film is close to 90°, the thickness in the corners of the step portion in the third insulating film is not thin. Therefore, since the thickness of the third insulating film is uniform, the film quality of the tunnel insulating film including the first, second and third insulating films is improved.

In the third non-volatile semiconductor storage device, it is preferable that the first insulating film and the second insulating film are thermal oxide films, and the third insulating film is an oxide film.

In the third non-volatile semiconductor storage device, it is preferable that the first insulating film is a thermal oxide film, the second insulating film is an oxynitride film formed by thermal oxidation, and the third insulating film is an oxynitride film.

A first method for producing a non-volatile semiconductor storage device includes a first step of forming a gate insulating film and a gate electrode sequentially on a semiconductor substrate; a second step of forming a side wall on a side face of the control gate electrode and then etching the semiconductor substrate using the formed side wall as a mask, thereby forming a first region on which the side wall is located, a second region obtained by etching the first region, and a step portion connecting the first region and the second region such that an angle formed between a side face of the step portion and an upper surface of the second region becomes an obtuse angle; a third step of removing the side wall and then forming an insulating film over the side face of the control gate electrode on the side of the step portion, the first region, the step portion and the second region; and a fourth step of forming a floating gate electrode on the side face of the control gate electrode on the side of the step portion and the second region including the step portion on the insulating film in a self-alignment manner.

According to the first method for producing a non-volatile semiconductor storage device, a first region on which the side wall is located, a second region obtained by etching the first region, and a step portion connecting the first region and the second region are formed such that the angle formed between the side face of the step portion and the upper surface of the second region becomes an obtuse angle. Therefore, the first non-volatile semiconductor storage device of the present invention can be obtained reliably.

It is preferable that in the second step of the first method for producing a non-volatile semiconductor storage device, the step portion and the second region are formed by isotropic dry etching.

It is preferable that in the second step of the first method for producing a non-volatile semiconductor storage device, the step portion and the second region are formed by wet etching.

It is preferable that in the second step of the first method for producing a non-volatile semiconductor storage device, the step portion and the second region are formed by dry etching and wet etching.

It is preferable that in the second step of the first method for producing a non-volatile semiconductor storage device, the angle formed between the side face of the step portion and the upper surface of the second region is about 100° or more.

It is preferable that in the second step of the first method for producing a non-volatile semiconductor storage device, the angle formed between the side face of the step portion and the upper surface of the second region is about 110° or more and about 130° or less.

A second method for producing a non-volatile semiconductor storage device of the present invention includes a first step of forming a gate insulating film and a gate electrode sequentially on a semiconductor substrate; a second step of forming a side wall on a side face of the control gate electrode and then etching the semiconductor substrate using the formed side wall as a mask, thereby forming a first region on which the side wall is located, a second region obtained by etching the first region, and a step portion connecting the first region and the second region; a third step of removing the side wall and then forming a first insulating film over the side face of the control gate electrode on the side of the step portion, the first region, the step portion and the second region by deposition; a fourth step of forming a second insulating film at the interface between the first insulating film and the side face of the control gate electrode on the side of the step portion, the first region, the step portion and the second region by thermal oxidation; and a fifth step of forming a floating gate electrode on the side face of the control gate electrode on the side of the step portion and the second region including the step portion on the first insulating film in a self-alignment manner.

According to the second method for producing a non-volatile semiconductor storage device, a second insulating film is formed at the interface between the first insulating film and the side face of the control gate electrode on the side of the step portion, the first region, the step portion and the second region by thermal oxidation. Thus, the second insulating film formed by thermal oxidation and the first insulating film formed by deposition are provided in this order from the step portion side. Therefore, the second non-volatile semiconductor storage device of the present invention can be obtained reliably.

It is preferable that in the third step of the second method for producing a non-volatile semiconductor storage device, the first insulating film is an oxynitride film.

It is preferable that in the fourth step of the second method for producing a non-volatile semiconductor storage device, the second insulating film is formed in an ambient containing nitrogen. With this, the first insulating film formed by deposition in the previous step can be nitridized during formation of the second insulating film.

It is preferable that the second method for producing a non-volatile semiconductor storage device further includes a step of performing an annealing treatment in a non-oxidative ambient with respect to the first insulating film and the second insulating film between the fourth step and the fifth step. With this, the film quality of the first insulating film formed by deposition is improved.

A third method for producing a non-volatile semiconductor storage device of the present invention includes a first step of forming a gate insulating film and a gate electrode sequentially on a semiconductor substrate; a second step of forming a side wall on a side face of the control gate electrode and then etching the semiconductor substrate using the formed side wall as a mask, thereby forming a first region on which the side wall is located, a second region obtained by etching the first region, and a step portion connecting the first region and the second region; a third step of removing the side wall and then forming a first insulating film over the side face of the control gate electrode on the side of the step portion, the first region, the step portion and the second region by thermal oxidation; a fourth step of forming a second insulating film on the first insulating film by deposition; a fifth step of forming a third insulating film at the interface between the first insulating film and the side face of the control gate electrode on the side of the step portion, the first region, the step portion and the second region by thermal oxidation; and a sixth step of forming a floating gate electrode on the side face of the control gate electrode on the side of the step portion and the second region including the step portion on the second insulating film in a self-alignment manner.

According to the third method for producing a non-volatile semiconductor storage device, a third insulating film is formed at the interface between the first insulating film and the side face of the control gate electrode on the side of the step portion, the first region, the step portion and the second region by thermal oxidation. Thus, the third and first insulating film formed by thermal oxidation and the second insulating film formed by deposition on the first insulating film are provided in this order from the step portion side. Therefore, the third non-volatile semiconductor storage device of the present invention can be obtained reliably.

It is preferable in the third method for producing a non-volatile semiconductor storage device that in the fourth step, the second insulating film is an oxynitride film.

It is preferable in the third method for producing a non-volatile semiconductor storage device that in the fifth step, the third insulating film is formed in an ambient containing nitrogen.

It is preferable that the third method for producing a non-volatile semiconductor storage device further includes a step of performing an annealing treatment in a non-oxidative ambient with respect to the first insulating film, the second insulating film and the third insulating film between the fifth step and the sixth step.

This and other advantages of the present invention will become apparent to those skilled in the art upon reading and understanding the following detailed description with reference to the accompanying figures.

### BRIEF DESCRIPTION OF THE DRAWINGS

FIG. 1 is a cross-sectional view showing a structure of a non-volatile semiconductor storage device of a first embodiment of the present invention.

FIG. 2 is a graph showing the constant current stress-charge to breakdown (Qbd) characteristics of a functional insulating film in the non-volatile semiconductor storage device of the first embodiment of the present invention, which is represented by the relationship between the tilt angle of the side face including the functional insulating film formed by thermal oxidation in the step portion of the semiconductor substrate and the constant current stress-charge to breakdown (Qbd) of the functional insulating film.

FIGS. 3A to 3C are cross sectional views of a process sequence showing a method for producing a non-volatile semiconductor storage device of the first embodiment of the present invention.

FIGS. 4A to 4C are cross sectional views of a process sequence showing a method for producing a non-volatile semiconductor storage device of the first embodiment of the present invention.

FIG. 5 is a cross sectional view showing a method for producing a non-volatile semiconductor storage device of the first embodiment of the present invention.

FIG. 6 is a perspective view showing a non-volatile semiconductor storage device of the first embodiment of the present invention.

FIG. 7 is a graph showing the constant current stress-charge to breakdown (Qbd) characteristics of a non-volatile semiconductor storage device of a second embodiment of the present invention, which is represented by the dependence of the constant current stress-charge to breakdown (Qbd) on the tilt angle of the step portion when an oxide film (HTO film) formed by a high temperature CVD method is used as the functional insulating film.

FIG. 8 is a cross-sectional view showing a structure of a non-volatile semiconductor storage device of a second embodiment of the present invention.

FIGS. 9A to 9C are cross sectional views of a process sequence showing a method for producing a non-volatile semiconductor storage device of the second embodiment of the present invention.

FIGS. 10A to 10C are cross sectional views of a process sequence showing a method for producing a non-volatile semiconductor storage device of the second embodiment of the present invention.

FIGS. 11A to 11C are cross sectional views showing a method for producing a non-volatile semiconductor storage device of the second embodiment of the present invention.

FIG. 12 is a perspective view showing a structure of a non-volatile semiconductor storage device of a third embodiment of the present invention.

FIGS. 13A to 13C are cross sectional views of a process sequence showing a method for producing a non-volatile semiconductor storage device of a third embodiment of the present invention.

FIGS. 14A to 14C are cross sectional views of a process sequence showing a method for producing a non-volatile semiconductor storage device of the third embodiment of the present invention.

FIGS. 15A to 15C are cross sectional views showing a method for producing a non-volatile semiconductor storage device of the third embodiment of the present invention.

FIG. 16 is a cross sectional view showing a method for producing a non-volatile semiconductor storage device of the third embodiment of the present invention.

FIG. 17 is a cross-sectional view showing a conventional split gate non-volatile semiconductor storage device.

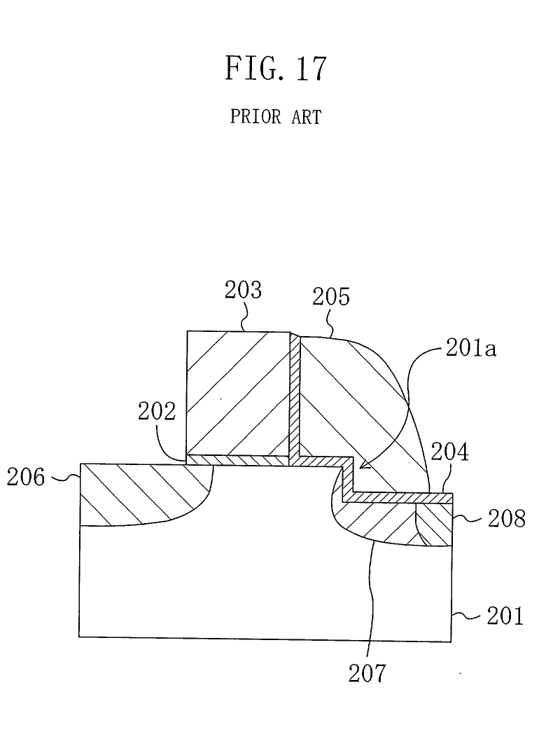

### DETAILED DESCRIPTION OF THE INVENTION

First Embodiment

A first embodiment of the present invention will be described with reference to the accompanying drawings.

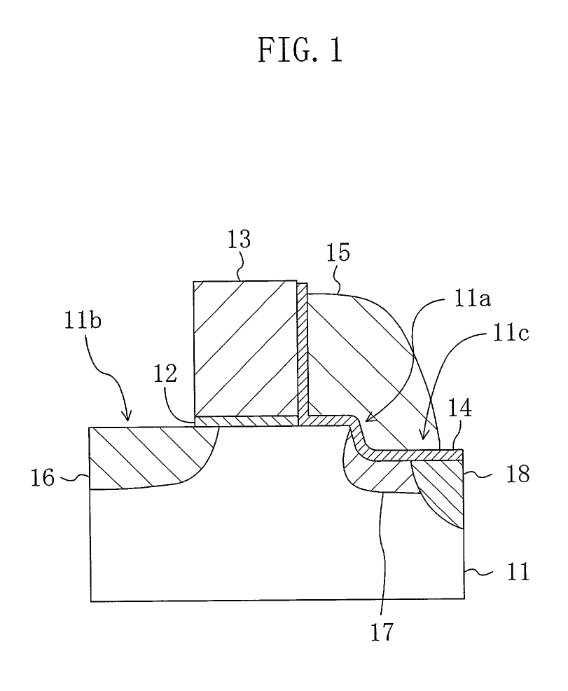

FIG. 1 shows a cross-sectional structure of a non-volatile semiconductor storage device of a first embodiment of the present invention. As shown in FIG. 1, a step portion 11a is provided in an upper portion of a semiconductor substrate 11 made of, for example, silicon (Si), and the step portion 11a separates a first region 11b that is the upper level thereof from a second region 11c that is the lower level thereof.

A control gate electrode 13 made of, for example, polysilicon is formed on the first region 11b of the semiconductor substrate 11 via a gate insulating film 12 made of, for example, silicon oxide.

A functional insulating film 14 made of, for example, silicon oxide is formed on the side face of the control gate electrode 13 on the side of the step portion 11a and on the first region 11b, the step portion 11a, and the second region 11c, and a floating gate electrode 15 made of, for example, polysilicon is formed on the functional insulating film 14 so as to straddle the step portion 11a. The functional insulating film 14 serves as a capacitance insulating film in a portion that is opposed to the control gate electrode 13, and serves as a tunnel insulating film in a portion that is opposed to the semiconductor substrate 11.

A source diffusion layer 16 is formed to the side face of the control gate electrode 13 in the first region 11b of the semiconductor substrate 11. An n-type low concentration drain diffusion layer 17 is formed below the floating gate electrode 15 in the second region 11c of the semiconductor substrate 11, and a high concentration drain diffusion layer 18 is formed outside the low concentration drain diffusion layer 17.

The first embodiment is characterized in that the side face of the step portion 11a forms an obtuse angle with respect to the upper surface of the second region 11c, and that the functional insulating film 14 has a substantially uniform thickness of about 9 nm to 11 nm at least on the step portion 11a.

As a result of various examinations regarding the angle formed by the step portion 11a with respect to the upper surface of the second region 11c by the inventors of the present application, it has been found that the angle is preferably about 100° or more, more preferably about 110° or more and about 130° or less.

Hereinafter, the relationship between the tilt angle of the step portion 11a and the quality of the film of the functional insulating film (tunnel film) will be described.

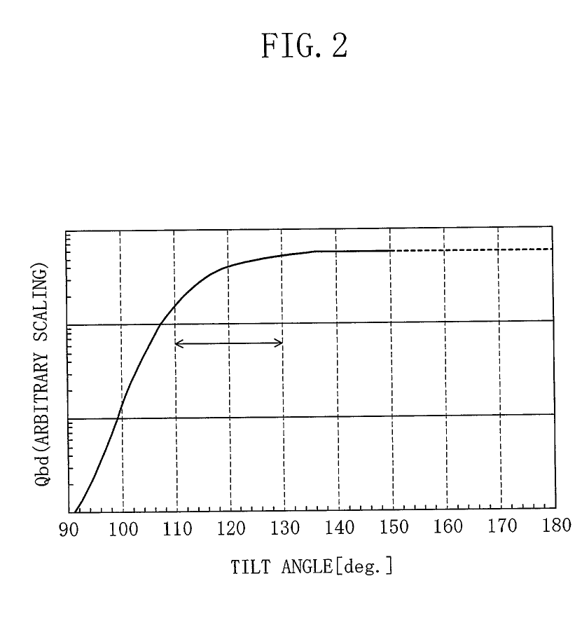

FIG. 2 shows the results of experiments regarding the relationship between the tilt angle of the side face including the functional insulating film 14 formed by thermal oxidation in the step portion 11a of the semiconductor substrate 11 and the constant current stress-charge to breakdown (CCS-Qbd) of the function insulating film 14 according to the first embodiment. In this embodiment, the functional insulating film 14 is a thermal oxide film having a thickness of 9 nm.

The tilt angle of the step portion 11a with respect to the upper surface of the second region 11c is formed in a range from 120° to 150° by using chemical dry etching (CDE) and changing the flow ratio of oxygen (O₂) and fluorocarbon (CF₄), which are etching gases for CDE, to change the etching selection ratio. The tilt angle of 120° or less is formed by reactive ion etching (RIE).

When the step portion 11a is subjected to thermal oxidation, the semiconductor substrate 11 is rounded by the stress of the thermal oxidation, so that the tilt angle is different between after the formation of the step portion 11a and after the thermal oxidation. In the first embodiment, it is confirmed that the tilt angle after the thermal oxidation is reduced by about 10 degrees from the tilt angle after the formation of the step portion 11a.

As shown in FIG. 2, the relationship between the tilt angle and the constant current stress-charge to breakdown differs greatly between the left and the right of the tilt angle of 110° in FIG. 2. More specifically, in the region where the tilt angle is more than 110°, a constant current stress-charge to breakdown substantially equal to that of the tunnel film formed on a flat substrate without the step portion 11a can be maintained. On the other hand, in a region where the tilt angle is 110° or less, the constant current stress-charge to breakdown is sharply reduced as the tilt angle is reduced.

This seems to be caused for the following reason. In a region where the tilt angle is small (close to a right angle), the thickness of the film in the corners on the upper level and the lower level of the step portion 11a in the functional insulating film 14 is locally small, so that the stress due to the electrical field concentrates thereon and the quality of the film is deteriorated. As a result, the constant current stress-charge to breakdown is reduced rapidly. On the other hand, when the tilt angle is as large as 110° or more, the thickness of the film in the corners in the step portion 11a in the functional insulating film 14 is not small, so that the quality of the film is improved and stabilized.

The constant current stress-charge to breakdown indicates the reliability of the functional insulating film 14. For the non-volatile semiconductor storage device of the first embodiment, a constant current stress-charge to breakdown equal to the thermal oxide film formed on a flat substrate without the step portion 11a is required. Accordingly, the tilt angle of the step portion 11a that satisfies this condition is 110° or more.

On the other hand, when the tilt angle after the formation of the step portion 11a is large, arsenic (As) ions, which are impurities, are implanted not only in the second region 11c, which is the lower level of the step portion 11a, but also in the side face of the step portion 11a, when forming the n-type low concentration drain region 17. If arsenic ions are implanted in the side face of the step portion 11a and an n-type region is formed, implantation of electrons to be written in the floating gate electrode 15 via the tunnel film on the side face of the step portion 11a is suppressed. Therefore, it is preferable that the tilt angle of the side face of the step portion 11a is small for improving the write rate.

These findings lead to the conclusion that the tilt angle after the formation of the functional insulating film 14 in the step portion 11a of the non-volatile semiconductor storage device according to the first embodiment is preferably about 110° or more and about 130° or less, and more preferably 120°, in order to improve the reliability as the tunnel film and the write rate of electrons at the same time.

Hereinafter, a method for producing a non-volatile semiconductor storage device according to the first embodiment having the above-described structure of the present invention will be described with reference to the accompanying drawings.

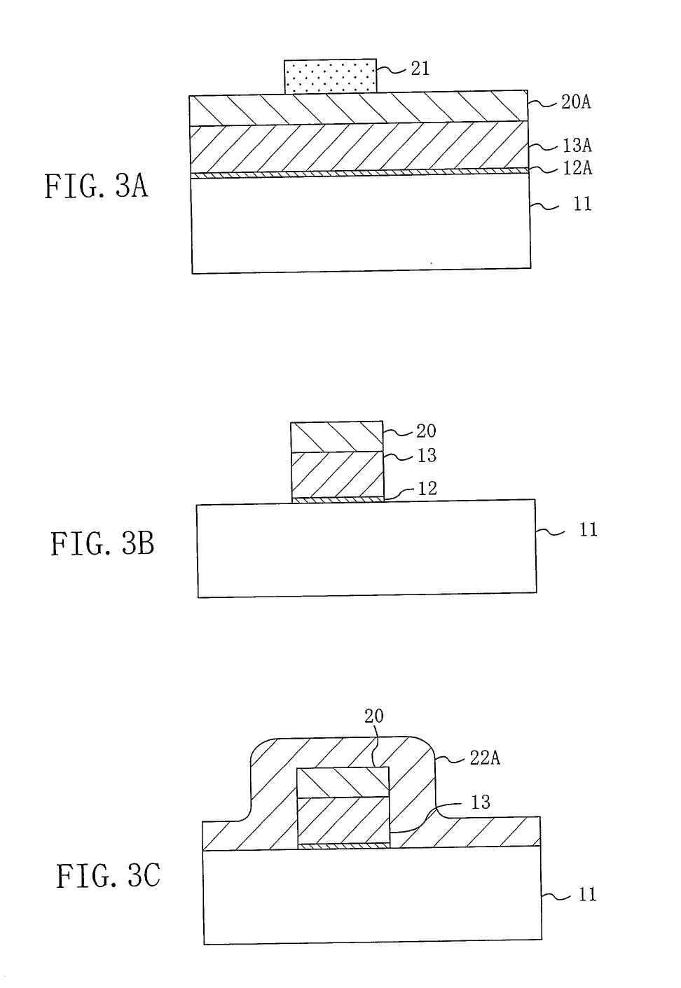

FIGS. 3A through 5 show a process sequence of a method for producing a non-volatile semiconductor storage device according to the first embodiment of the present invention.

First, as shown in FIG. 3A, a gate insulating film forming film 12A made of silicon oxide having a thickness of about 9 nm on the principle surface of a semiconductor substrate 11 by thermal oxidation. Then, a gate electrode forming film 13A made of polycrystalline silicon having a thickness of about 200 nm to 300 nm and a protective film 20A made of silicon nitride or silicon oxide having a thickness of about 100 nm to 200 nm are formed sequentially on the gate insulating film forming film 12A by chemical vapor deposition (CVD). Thereafter, a first resist mask 21 having a control gate electrode pattern is formed on the protective film 20A by lithography.

Next, as shown in FIG. 3B, using the formed first resist mask 21, anisotropic dry etching is performed with respect to the protective film 20A, the gate electrode forming film 13A, and the gate insulating film forming film 12A so that a patterned protective film 20, a control gate electrode 13, and a gate insulating film 12 are obtained.

Next, as shown in FIG. 3C, the first resist mask 21 is removed, and then a BPSG (boron phosphide silicate glass) film 22A having a thickness of about 30 nm to 50 nm is deposited over the entire surface of the semiconductor substrate 11 including the control gate electrode 13 and the protective film 20 by CVD.

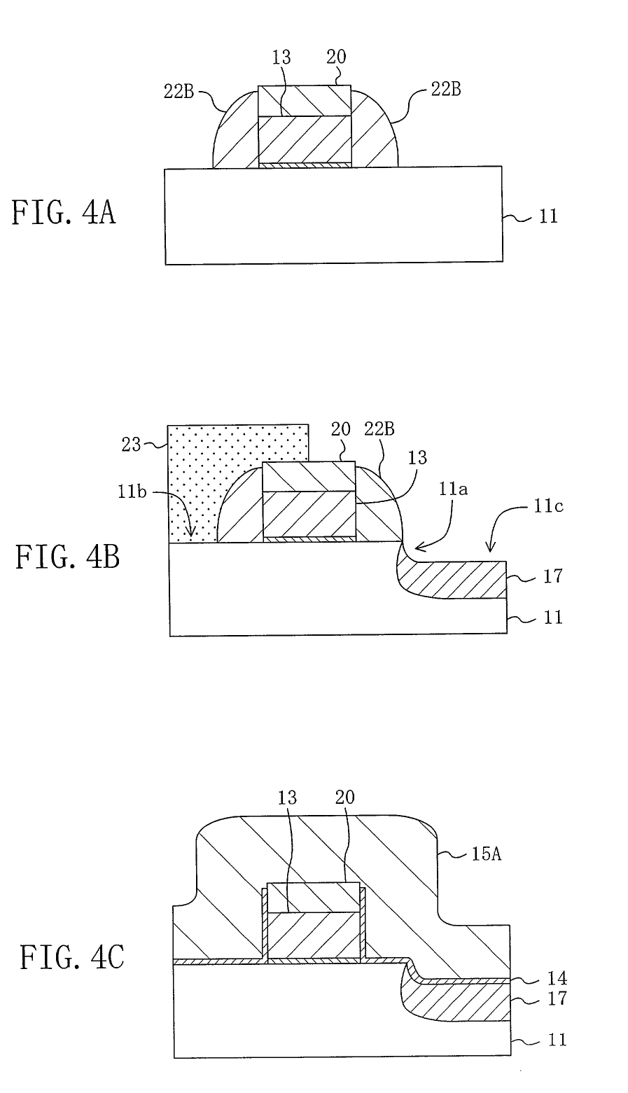

As shown in FIG. 4A, etchback is performed with respect to the deposited BPSG film 22A by anisotropic dry etching so that side walls 22B made of the BPSG film 22A are formed on the side faces of the control gate electrode 13.

Next, as shown in FIG. 4B, a second resist mask 23 is formed on the side of the source forming region on the semiconductor substrate 11 including the side portion of the protective film 20, and isotropic dry etching is performed with respect to the semiconductor substrate 11, using the formed second resist mask 23, the protective film 20, and the side walls 22B as a mask, for example, with CF₄ or NF₃ as the etching gas. Then, the first region 11b on which the side walls 22B are located, the second region 11c formed by etching the first region 11b, and the step portion 11a connecting the first region 11b and the second region 11c are formed such that the angle formed between the side face of the step portion 11a and the upper surface of the second region 11c is about 110° or more and about 130° or less. The depth of the second region 11c is about 30 nm.

As methods for improving the quality of the functional insulating film 14 on the step portion 11a, the following methods other than increasing the tilt angle by chemical dry etching can be used: The step portion 11a is formed on the semiconductor substrate 11 by dry etching, and then the tilt angle of the step portion 11a is increased by wet etching, for example, with an alkali solution such as ammonium hydroxide (NH₄OH) as the etchant; or the step portion 11a is formed on the semiconductor substrate 11 by dry etching, and then the semiconductor substrate 11 is subjected to thermal oxidation to round the step portion 11a, and then the thermal oxide film is removed by wet etching to increase the tilt angle of the step portion 11a. Either one of the above-described methods can be used to improve the quality of the functional insulating film 14, which is formed after the formation of the step portion 11a.

Then, with the second resist mask 23, the protective film 20 on the control gate electrode 13 and the side walls 22B as a mask, arsenic ions are implanted on the semiconductor substrate 11, for example, at an implantation dose amount of 0.5×10¹⁴ cm⁻² to 5×10¹⁴ cm⁻² and an implantation energy of about 10 keV to form an n-type low concentration drain diffusion layer 17 in the drain forming region.

Next, as shown in FIG. 4C, after the second resist mask 23 and the side walls 22B are removed, a functional insulating film 14 having a thickness of about 9 nm is formed in the exposed portion of the semiconductor substrate 11 and the side face of the control gate electrode 13 by thermal oxidation (wet oxidation) at 850° C. for about 10 minutes with oxygen gas and hydrogen gas. Then, a floating gate electrode forming film 15A made of polycrystalline silicon having a thickness of about 100 nm is deposited over the entire surface including the control gate electrode 13 and the protective film 20 on the functional insulating film 14 by CVD.

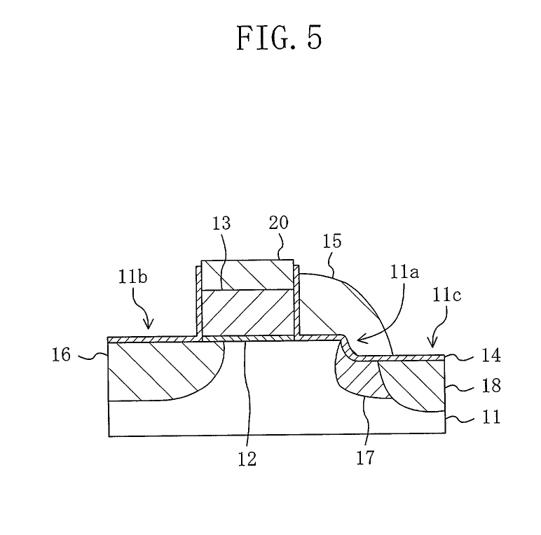

Next, as shown in FIG. 5, etchback is performed with respect to the deposited floating gate electrode forming film 15A by anisotropic dry etching to form a floating gate electrode 15 made of the floating gate electrode forming film 15A on the side face of the control electrode 13 on the side of the step portion 11a and in the second region 11c including the step portion 11a on the functional insulating film 14. Thus, the floating gate electrode 15 straddles the step portion 11a via the functional insulating film 14 serving as the tunnel insulating film, and is opposed to the control gate electrode 13 via the functional insulating film 14 serving as the capacitance insulating film at their side faces. Thereafter, arsenic ions are implanted in the semiconductor substrate 11 with the protective film 20 on the control gate electrode 13 and the floating gate electrode 15 as a mask, so that a source diffusion layer 16 is formed in the first region 11b of the semiconductor substrate 11, and a high concentration drain diffusion layer 18 that is connected to the low concentration drain region 17 is formed in the second region 11c of the semiconductor substrate 11.

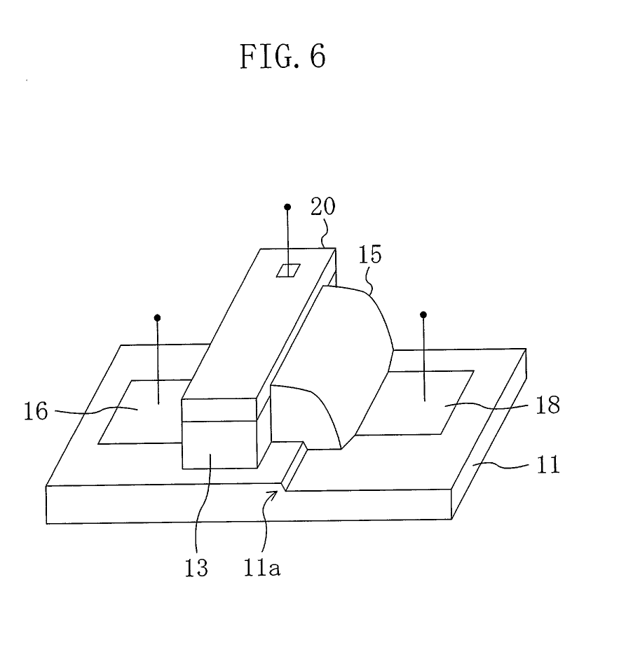

Thereafter, predetermined lines and interlayer insulating films are formed, although not shown, so that one memory element of the non-volatile semiconductor storage device of the first embodiment, as shown in the perspective view of FIG. 6, can be obtained.

Second Embodiment

Hereinafter, a second embodiment of the present invention will be described.

In order to make the thickness of the functional insulating film serving as the tunnel insulating film uniform, the side face of the step portion is formed so as to have a tilt angle of 100° or more. Other than this, the inventors of the present application also have found that the thickness can be substantially uniform by using an insulating film obtained by deposition as the functional insulating film, even if the tilt angle of the side face of the step portion is substantially a right angle.

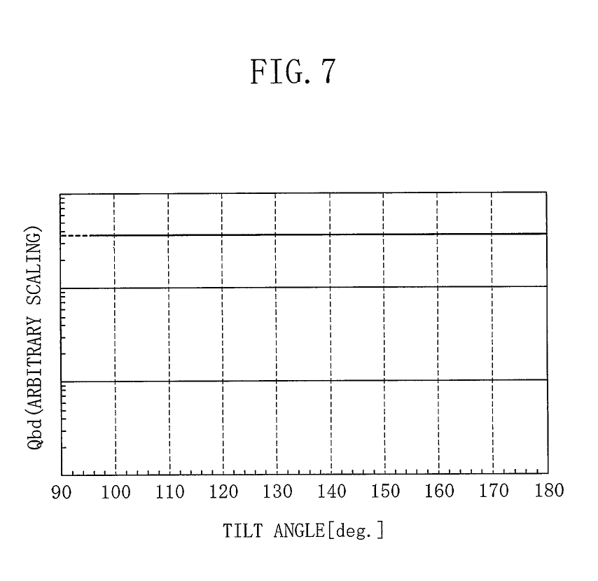

FIG. 7 shows the dependence of the constant current stress-charge to breakdown on the tilt angle of the step portion when an oxide film formed by high temperature CVD instead of thermal oxidation, a so-called HTO (high temperature oxide) film, is used as the functional insulating film.

As shown in FIG. 7, when an oxide film formed by deposition (hereinafter, referred to as “deposited oxide film”) is used as the functional insulating film, the constant current stress-charge to breakdown does not depend on the tilt angle of the step portion. This is because the thickness of the deposited oxide film is not small locally in the corners of the step portion as opposed to the thermal oxide film, even if the tilt angle of the step portion is small (close to 90°). In general, the deposited oxide film has a smaller density of silicon that is oxidized than the thermal oxide film, and therefore a dense oxide film can hardly be obtained, so that more defects occur in the film.

Therefore, in the second embodiment, after a deposited oxide film is formed, a thermal oxide film is formed via the deposited oxide film on the side of the substrate. Thus, a multilayered film including the thermal oxide film and the deposited oxide film is formed as the functional insulating film in order to prevent the non-uniformity of the thickness arising from the corners of the step portion in the functional insulating film and improve the quality of the film.

Hereinafter, a specific example of a non-volatile semiconductor storage device of the present invention will be described with reference to the accompanying drawings.

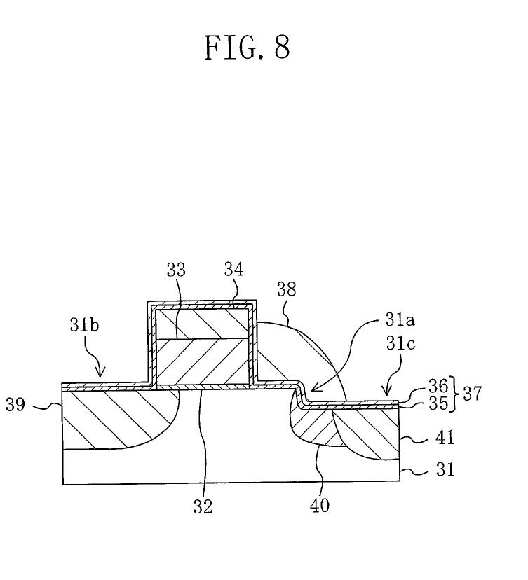

FIG. 8 is a cross-sectional structure of a non-volatile semiconductor storage device of the second embodiment of the present invention. As shown in FIG. 8, a step portion 31a is formed in an upper portion of a semiconductor substrate 31 made of, for example, silicon, and the step portion 11a separates a first region 31b that is the upper level thereof from a second region 31c that is the lower level thereof.

A control gate electrode 33 made of, for example, polysilicon is formed on the first region 31b of the semiconductor substrate 31 via a gate insulating film 32 made of, for example, silicon oxide. A protective film 34 for protecting the control gate electrode 33 made of, for example, silicon nitride or silicon oxide is formed on the control gate electrode 33.

A functional insulating film 37 including a thermal oxide film 35 and a deposited oxide film 36, for example, both of which are made of silicon oxide, is formed on the control gate electrode 33, the first region 31b, the step portion 31a, and the second region 31c.

A floating gate electrode 38 made of, for example, polysilicon is formed on the functional insulating film 37. The functional insulating film 37 serves as a capacitance insulating film in a portion that is opposed to the control gate electrode 33, and serves as a tunnel insulating film in a portion that is opposed to the semiconductor substrate 31.

A source diffusion layer 39 is formed to the side face of the control gate electrode 33 in the first region 31b of the semiconductor substrate 31. An n-type low concentration drain diffusion layer 40 is formed below the floating gate electrode 38 in the second region 31c of the semiconductor substrate 31, and a high concentration drain diffusion layer 41 is formed outside the low concentration drain diffusion layer 40.

The second embodiment is characterized in that the functional insulating film 37 has a multilayered structure including the thermal oxide film 35 and the deposited oxide film 36 and has a substantially uniform thickness of about 9 nm to 11 nm on the step portion 31a.

Hereinafter, a method for producing a non-volatile semiconductor storage device according to the second embodiment having the above-described structure of the present invention will be described with reference to the accompanying drawings.

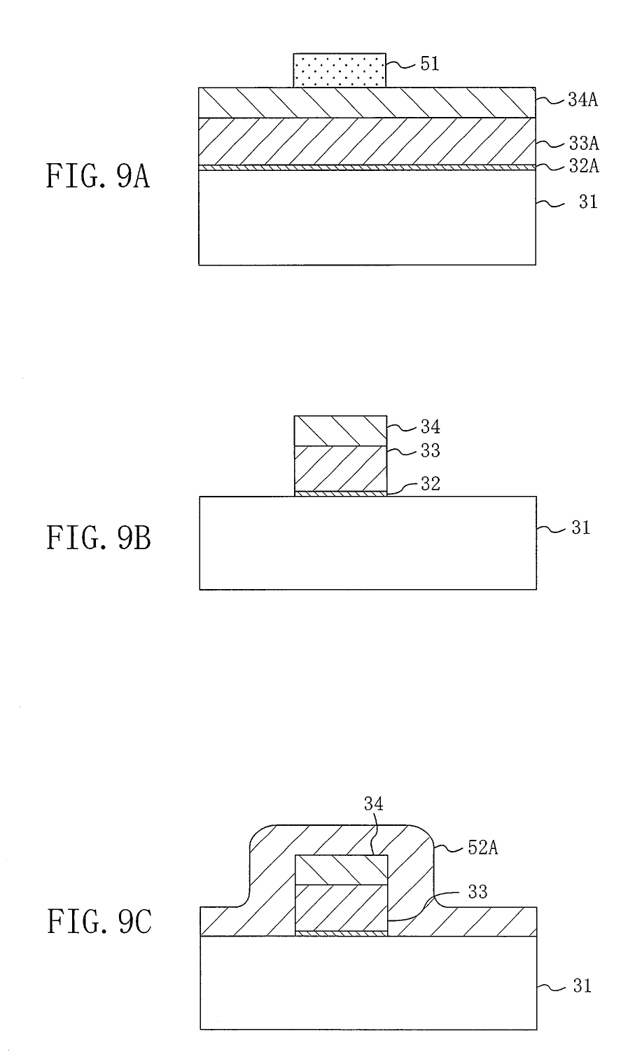

FIGS. 9A through 11C show a process sequence of a method for producing a non-volatile semiconductor storage device according to the second embodiment of the present invention.

First, as shown in FIG. 9A, a gate insulating film forming film 32A made of silicon oxide having a thickness of about 9 nm on the principle surface of a semiconductor substrate 31 by thermal oxidation. Then, a gate electrode forming film 33A made of polycrystalline silicon having a thickness of about 200 nm to 300 nm and a protective film 34A made of silicon nitride having a thickness of about 100 nm to 200 nm are formed sequentially on the gate insulating film forming film 32A by CVD. Thereafter, a first resist mask 51 having a control gate electrode pattern is formed on the protective film 34A by lithography.

Next, as shown in FIG. 9B, using the formed first resist mask 51, anisotropic dry etching is performed with respect to the protective film 34A, the gate electrode forming film 33A and the gate insulating film forming film 32A so that a patterned protective film 34, a control gate electrode 33, and a gate insulating film 32 are obtained.

Next, as shown in FIG. 9C, the first resist mask 51 is removed, and then a BPSG film 52A having a thickness of about 30 nm to 50 nm is deposited over the entire surface of the semiconductor substrate 31 including the control gate electrode 33 by CVD.

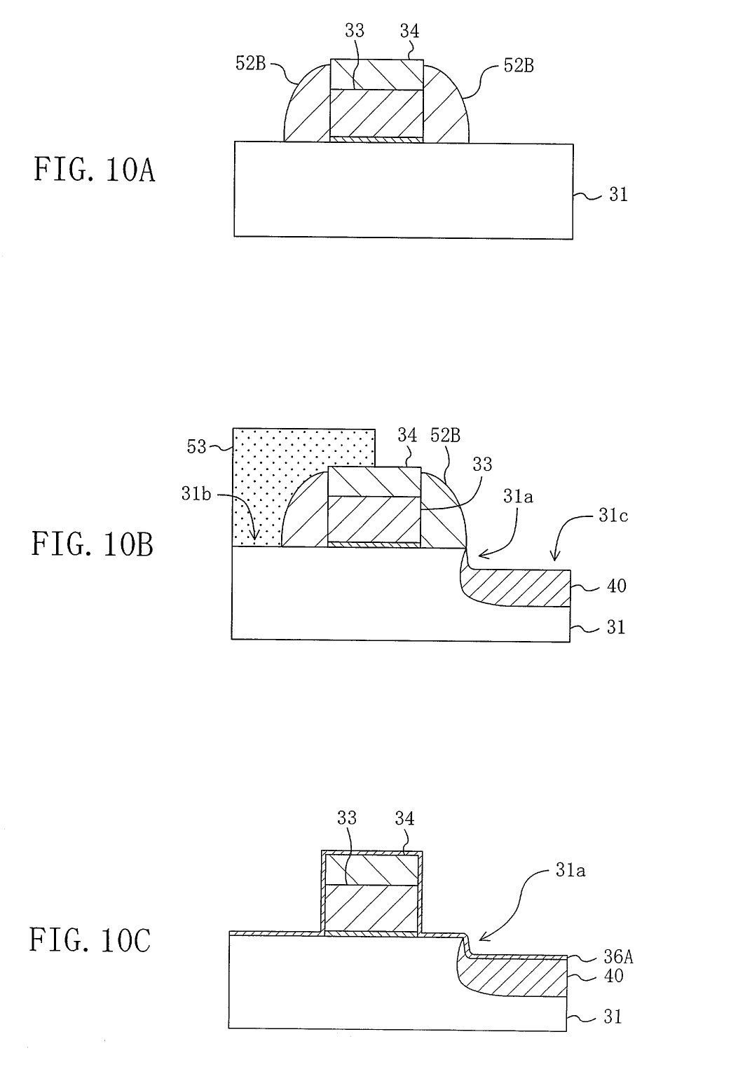

As shown in FIG. 10A, etchback is performed with respect to the deposited BPSG film 52A by anisotropic dry etching so that side walls 52B made of the BPSG film 52A are formed on the side face of the control gate electrode 33.

Next, as shown in FIG. 10B, a second resist mask 53 is formed on the side of the source forming region on the semiconductor substrate 31 including the side portion of the protective film 34, and for example, isotropic dry etching is performed with respect to the semiconductor substrate 31, using the formed second resist mask 53, the protective film 34, and the side walls 52B as a mask, to form the first region 31b on which the side walls 52B are located, the second region 31c formed by etching the first region 31b, and the step portion 31a connecting the first region 31b and the second region 31c. The depth of the second region 31c is about 30 nm. Thereafter, with the second resist mask 53, and the protective film 34 on the control gate electrode 33 and the side walls 52B as a mask, arsenic ions are implanted on the semiconductor substrate 31, for example, at an implantation dose amount of about 0.5×10¹⁴ cm⁻² to 5×10¹⁴ cm⁻² and an implantation energy of about 10 keV to form an n-type low concentration drain diffusion layer 40 in the drain forming region.

Next, as shown in FIG. 10C, after the second resist mask 53 and the side walls 52B are removed, a deposited oxide film 36A having a thickness of about 5 nm made of, for example, HTO is deposited over the entire surface of the semiconductor substrate 31 including the control gate electrode 33 and the protective film 34 by CVD.

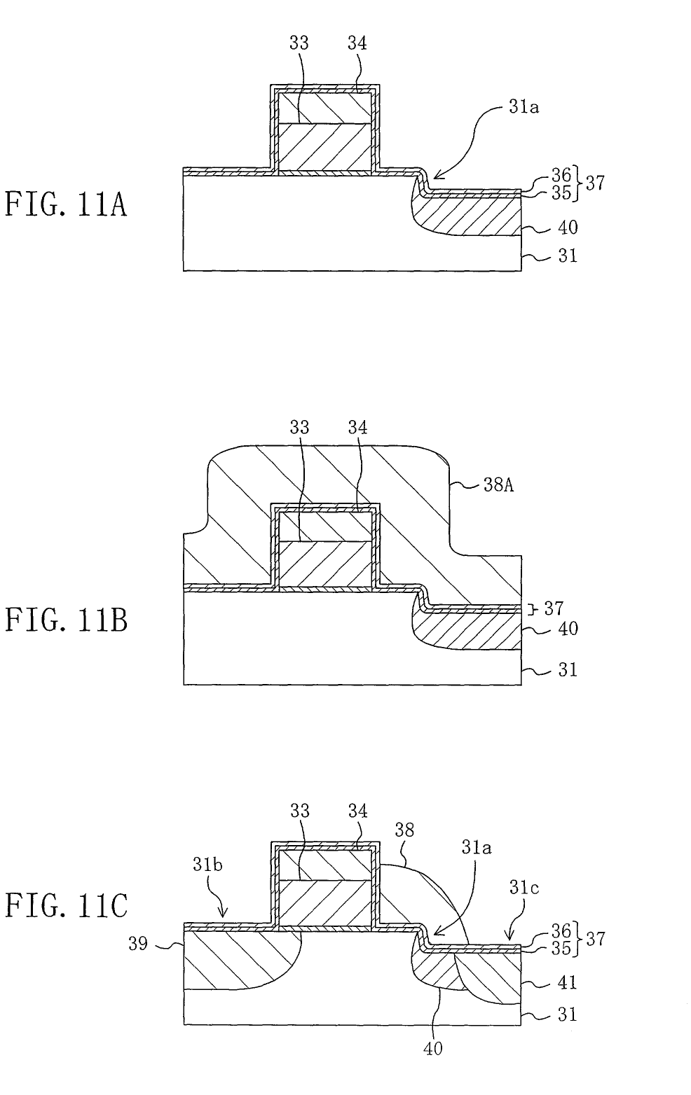

Next, as shown in FIG. 11A, a thermal oxide film 35 having a thickness of about 7 nm is formed at the interface between the deposited oxide film 36A and the semiconductor substrate 31 and the control gate electrode 33. Thus, the oxidation density of the deposited oxide film 36A is increased so that a deposited oxide film 36 having improved film quality can be obtained, and at the same time, a functional insulating film 37 having a total thickness of about 9 nm to 11 nm including the deposited oxide film 36 and the thermal oxide film 35 therebelow is formed.

In FIG. 10C, the deposited oxide film 36A may be an oxynitride film. In FIG. 11A, nitrogen monoxide (NO), nitrous oxide (N₂O), or ammonia (NH₃) gas may be added to the ambient for thermal oxidation to form an oxynitride film as the deposited oxide film 36. With this, the breakdown voltage property of the functional insulating film 37 can be improved.

Next, as shown in FIG. 11B, a floating gate electrode forming film 38A made of polycrystalline silicon having a thickness of about 100 nm is deposited over the entire surface of the functional insulating film 37 including the control gate electrode 33 and the protective film 34 by CVD.

Next, as shown in FIG. 11C, etchback is performed with respect to the deposited floating gate electrode forming film 38A by anisotropic dry etching to form a floating gate electrode 38 made of the floating gate electrode forming film 38A on the side face of the control electrode 33 on the side of the step portion 31a and in the second region 31c including the step portion 31a on the functional insulating film 37. Thus, the floating gate electrode 38 straddles the step portion 31a via the functional insulating film 37 serving as the tunnel insulating film, and is opposed to the control gate electrode 33 via the functional insulating film 37 serving as the capacitance insulating film at their side faces. Thereafter, arsenic ions are implanted in the semiconductor substrate 31 with the protective film 34 on the control gate electrode 33 and the floating gate electrode 38 as a mask, so that a source diffusion layer 39 is formed in the first region 31b of the semiconductor substrate 31, and a high concentration drain diffusion layer 41 that is connected to the low concentration drain region 40 is formed in the second region 31c of the semiconductor substrate 31.

Thereafter, predetermined lines and interlayer insulating films (not shown) are formed, so that one memory element of the non-volatile semiconductor storage device of the second embodiment can be obtained.

As described above, according to the second embodiment, the functional insulating film 37 serving as the tunnel insulating film on the step portion 31a provided in an upper portion of the semiconductor substrate 31 is constituted by the thermal oxide film 35 and the deposited oxide film 36, and therefore even if the tilt angle of the side face of the step portion 31a is an obtuse angle of less than 100, the functional insulating film 37 can be prevented from being thin locally in the corners of the step 31a. Therefore, the film quality of the functional insulating film 37 can be improved and thus the reliability of the functional insulating film 37 can be improved.

If an annealing treatment is formed in a non-oxidative ambient such as nitrogen gas at a temperature of, for example 800 C. to 900 C. for about 10 to 30 minutes after the process for forming the thermal oxide film as shown in FIG. 11A, the film quality of the functional insulating film 37 can be further improved with the thickness thereof maintained.

Third Embodiment

Hereinafter, a third embodiment of the present invention will be described.

In the above-described second embodiment, after the deposited oxide film is formed in the step portion, the semiconductor substrate is thermally oxidized via the deposited oxide film to form the function insulating film so that the influence of the corners of the step portion on the functional insulating film can be eliminated.

In the third embodiment, in order to reduce further the influence of the corners of the step portion on the functional insulating film, a thin first thermal oxide film is formed on the surface of the step portion with a rapid thermal process (RTP) of thermal oxidation methods, and then a deposited oxide film is deposited on the formed first thermal oxide film, and further a second thermal oxide film is formed on the first oxide film on the side of the substrate via the deposited oxide film.

Hereinafter, a specific example of a non-volatile semiconductor storage device of the present invention will be described with reference to the accompanying drawings.

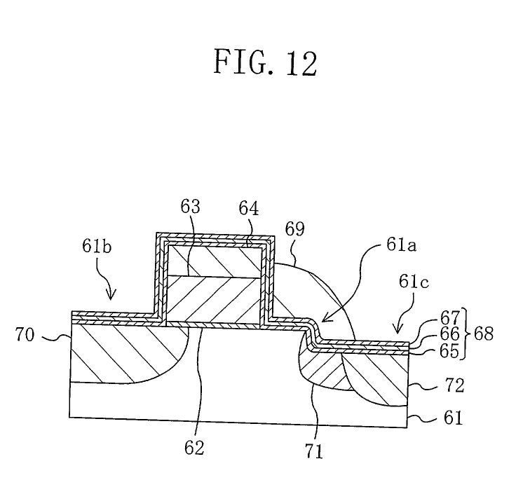

FIG. 12 is a cross-sectional structure of a non-volatile semiconductor storage device of the third embodiment of the present invention. As shown in FIG. 12, a step portion 61a is formed in an upper portion of a semiconductor substrate 61 made of, for example, silicon, and the step portion 61a separates a first region 61b that is the upper level thereof from a second region 61c that is the lower level thereof.

A control gate electrode 63 made of, for example, polysilicon is formed on the first region 61b of the semiconductor substrate 61 via a gate insulating film 62 made of, for example, silicon oxide. A protective film 64 for protecting the control gate electrode 63 made of, for example, silicon nitride or silicon oxide is formed on the control gate electrode 63.

A functional insulating film 68 including a second thermal oxide film 65, a first thermal oxide film 66 and a deposited oxide film 67, all of which are made of, for example, silicon oxide, is formed on the control gate electrode 63, the first region 61b, the step portion 61a, and the second region 61c.

A floating gate electrode 69 made of, for example, polysilicon is formed on the functional insulating film 68. The functional insulating film 68 serves as a capacitance insulating film in a portion that is opposed to the control gate electrode 63, and serves as a tunnel insulating film in a portion that is opposed to the semiconductor substrate 61.

A source diffusion layer 70 is formed to the side face of the control gate electrode 63 in the first region 61b of the semiconductor substrate 61. An n-type low concentration drain diffusion layer 71 is formed below the floating gate electrode 69 in the second region 61c of the semiconductor substrate 61, and a high concentration drain diffusion layer 72 is formed outside the low concentration drain diffusion layer 71.

The third embodiment is characterized in that the functional insulating film 68 has a multilayered structure including the second thermal oxide film 65, the first thermal oxide film 66 and the deposited oxide film 67 and has a substantially uniform thickness of about 9 nm to 11 nm on the step portion 61a.

Hereinafter, a method for producing a non-volatile semiconductor storage device according to the third embodiment having the above-described structure will be described with reference to the accompanying drawings.

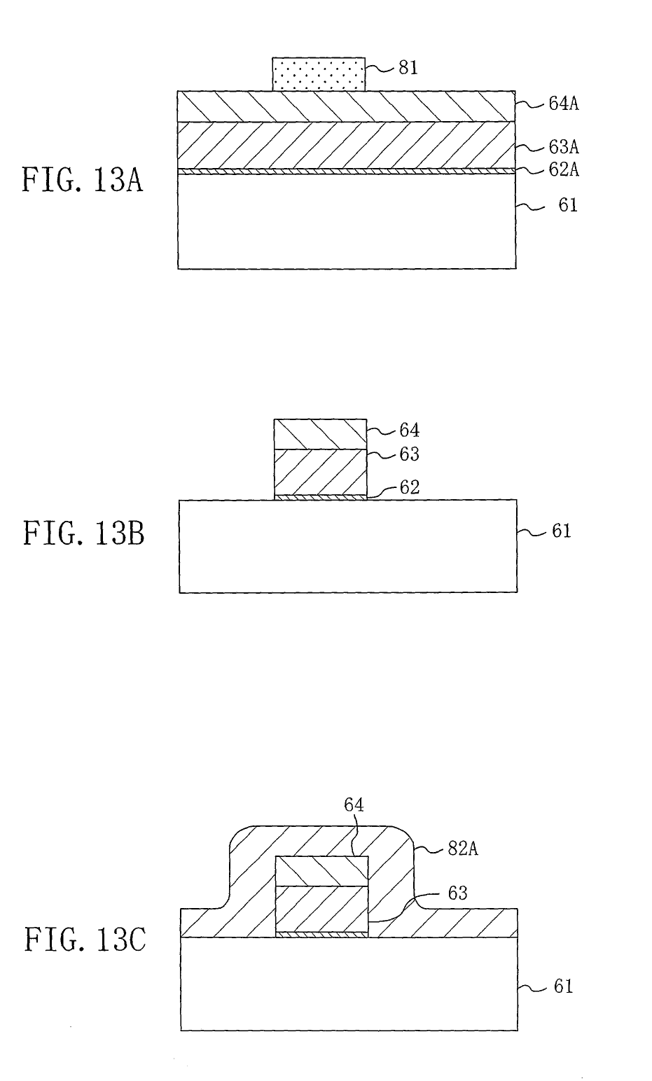

FIGS. 13A through 16 show a process sequence of a method for producing a non-volatile semiconductor storage device according to the third embodiment of the present invention.

First, as shown in FIG. 13A, a gate insulating film forming film 62A made of silicon oxide having a thickness of about 9 nm on the principle surface of a semiconductor substrate 61 by thermal oxidation. Then, a gate electrode forming film 63A made of polycrystalline silicon having a thickness of about 200 nm to 300 nm and a protective film 64A made of silicon nitride having a thickness of about 100 nm to 200 nm are formed sequentially on the gate insulating film forming film 62A by CVD. Thereafter, a first resist mask 81 having a control gate electrode pattern is formed on the protective film 64A by lithography.

Next, as shown in FIG. 13B, using the formed first resist mask 81, anisotropic dry etching is performed with respect to the protective film 64A, the gate electrode forming film 63A and the gate insulating film forming film 62A so that a patterned protective film 64, a control gate electrode 63, and a gate insulating film 62 are obtained.

Next, as shown in FIG. 13C, the first resist mask 81 is removed, and then a BPSG film 82A having a thickness of about 30 nm to 50 nm is deposited over the entire surface of the semiconductor substrate 61 including the control gate electrode 63 by CVD.

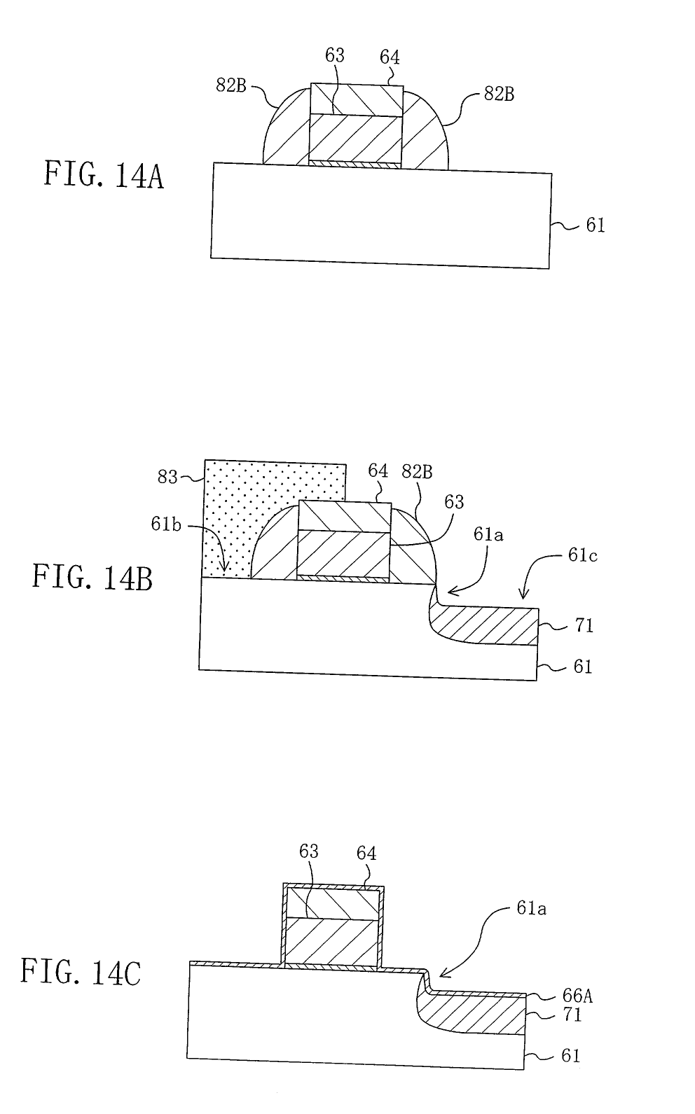

As shown in FIG. 14A, etchback is performed with respect to the deposited BPSG film 82A by anisotropic dry etching so that side walls 82B made of the BPSG film 82A are formed on the side face of the control gate electrode 63.

Next, as shown in FIG. 14B, a second resist mask 83 is formed on the side of the source forming region on the semiconductor substrate 61 including the side portion of the protective film 64, and for example, isotropic dry etching is performed with respect to the semiconductor substrate 61, using the formed second resist mask 83, the protective film 64, and the side walls 82B as a mask, to form the first region 61b on which the side walls 82B are located, the second region 61c formed by etching the first region 61b, and the step portion 61a connecting the first region 61b and the second region 61c. The depth of the second region 61c is about 30 nm. Thereafter, with the second resist mask 83, the protective film 64 on the control gate electrode 63 and the side walls 82B as a mask, arsenic ions are implanted into the semiconductor substrate 61, for example, at an implantation dose amount of 0.5×10¹⁴ cm⁻² to 5×10¹⁴ cm⁻² and an implantation energy of about 10 keV to form an n-type low concentration drain diffusion layer 71 in the drain forming region.

Next, as shown in FIG. 14C, after the second resist mask 83 and the side walls 82B are removed, a first thermal oxide film 66A having a thickness of about 2 nm to 5 nm is formed in the exposed portion of the semiconductor substrate 61 and the side face of the control gate electrode 63 is formed by thermal oxidation by a rapid thermal process.

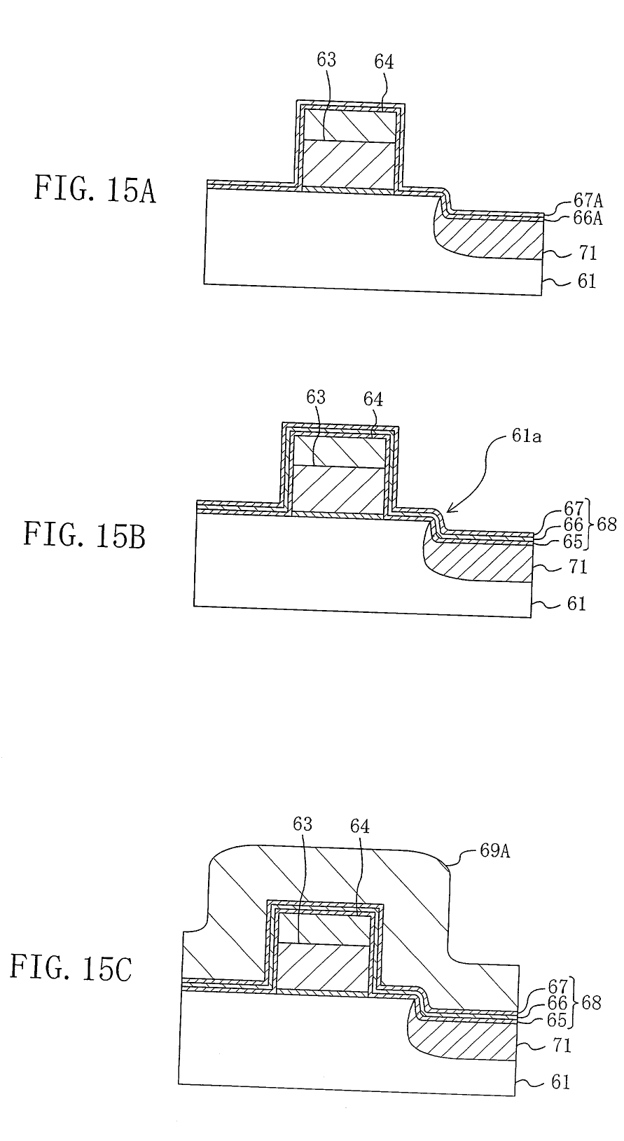

Then, as shown in FIG. 15A, a deposited oxide film 67A having a thickness of about 3 nm made of, for example, HTO is deposited over the entire surface of the first thermal oxide film 66A by CVD.

Next, as shown in FIG. 15B, a second thermal oxide film 65 having a thickness of about 7 nm is formed at the interface between the first thermal oxide film 66A and the semiconductor substrate 61 and the control gate electrode 63. Thus, the oxidation density of the deposited oxide film 67A and the first thermal oxide film 66A is increased so that a deposited oxide film 67 and a first thermal oxide film 66 having improved film quality can be obtained, and at the same time, a functional insulating film 68 having a total thickness of about 9 nm to 11 nm including the deposited oxide film 67, the first thermal oxide film 66 and the second thermal oxide film 65 therebelow is formed.

In FIG. 15A, the deposited oxide film 67A may be an oxynitride film. In FIG. 15B, nitrogen monoxide, nitrous oxide, or ammonia gas may be added to the ambient for thermal oxidation to form an oxynitride film as the deposited oxide film 67. With this, the breakdown voltage property of the functional insulating film 68 can be improved.

Next, as shown in FIG. 15C, a floating gate electrode forming film 69A made of polycrystalline silicon having a thickness of about 100 nm is deposited over the entire surface of the functional insulating film 68 including the control gate electrode 63 and the protective film 64 by CVD.

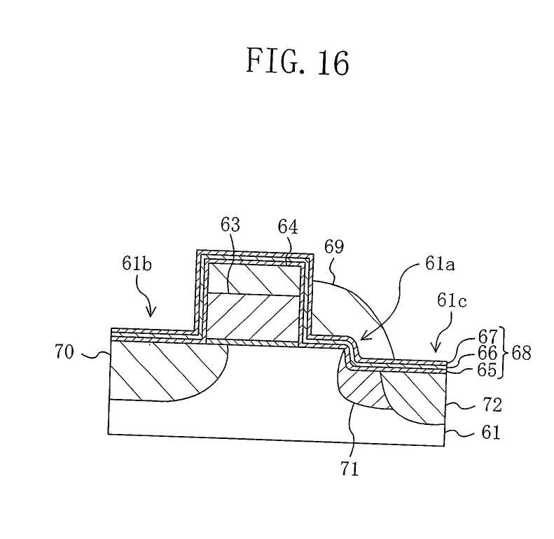

Next, as shown in FIG. 16, etchback is performed with respect to the deposited floating gate electrode forming film 69A by anisotropic dry etching to form a floating gate electrode 69 made of the floating gate electrode forming film 69A on the side face of the control electrode 63 on the side of the step portion 61a and in the second region 61c including the step portion 61a on the functional insulating film 68. Thus, the floating gate electrode 69 straddles the step portion 61a via the functional insulating film 69 serving as the tunnel insulating film, and is opposed to the control gate electrode 63 via the functional insulating film 68 serving as the capacitance insulating film at their side faces. Thereafter, arsenic ions are implanted in the semiconductor substrate 61 with the protective film 64 on the control gate electrode 63 and the floating gate electrode 69 as a mask, so that a source diffusion layer 70 is formed in the first region 61b of the semiconductor substrate 61, and a high concentration drain diffusion layer 72 that is connected to the low concentration drain region 71 is formed in the second region 61c of the semiconductor substrate 61.

Thereafter, predetermined lines and interlayer insulating films (not shown) are formed, so that one memory element of the non-volatile semiconductor storage device of the third embodiment can be obtained.

As described above, according to the third embodiment, the functional insulating film 68 serving as the tunnel insulating film on the step portion 61a provided in an upper portion of the semiconductor substrate 61 is constituted by the second thermal oxide film 65, the first thermal oxide film 66, and the deposited oxide film 67, and therefore even if the tilt angle of the side face of the step portion 61a is an obtuse angle of less than 100, the functional insulating film 68 can be prevented from being thin locally in the corners of the step 61a. Therefore, the film quality of the functional insulating film 68 can be improved and thus the reliability of the functional insulating film 68 can be improved.

If an annealing treatment is formed in a non-oxidative ambient such as nitrogen gas at a temperature of, for example about 850 C. for about 90 minutes after the process for forming the second thermal oxide film as shown in FIG. 15B, the film quality of the functional insulating film 68 can be further improved with the thickness thereof maintained.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A non-volatile semiconductor storage device comprising:
a semiconductor substrate provided with a step portion in an upper portion thereof, and having a first region that is an upper level of the step portion and a second region that is a lower level thereof;
a control gate electrode formed on the first region of the semiconductor substrate via a gate insulating film; and
a floating gate electrode formed on a side face of the control gate electrode on a side of the step portion and on the step portion via an insulating film;
wherein a side face of the step portion forms an obtuse angle with respect to an upper surface of the second region, and
the insulating film has a substantially uniform thickness on the step portion.

2. The non-volatile semiconductor storage device according to claim 1,
wherein an angle formed between the side face of the step portion and the upper surface of the second region is about 100° or more.

3. The non-volatile semiconductor storage device according to claim 1,
wherein an angle formed between the side face of the step portion and the upper surface of the second region is about 110° or more and about 130° or less.

4. The non-volatile semiconductor storage device according to claim 1,
wherein the insulating film is a thermal oxide film.

5. A non-volatile semiconductor storage device comprising:
a semiconductor substrate provided with a step portion in an upper portion thereof, and having a first region that is an upper level of the step portion and a second region that is a lower level thereof;
a control gate electrode formed on the first region of the semiconductor substrate via a gate insulating film; and
a floating gate electrode formed on a side face of the control gate electrode on a side of the step portion and on the step portion via a first insulating film and a second insulating film provided in this order from the substrate;
wherein the second insulating film is formed with a deposited film.

6. The non-volatile semiconductor storage device according to claim 5,
wherein the first insulating film is a thermal oxide film, and the second insulating film is an oxide film.

7. The non-volatile semiconductor storage device according to claim 5,
wherein the first insulating film is a thermal oxide film, and the second insulating film is an oxynitride film.

8. A non-volatile semiconductor storage device comprising:
a semiconductor substrate provided with a step portion in an upper portion thereof, and having a first region that is an upper level of the step portion and a second region that is a lower level thereof;
a control gate electrode formed on the first region of the semiconductor substrate via a gate insulating film; and
a floating gate electrode formed on a side face of the control gate electrode on a side of the step portion and on the step portion via a first insulating film, a second insulating film and a third insulating film provided in this order from the substrate;
wherein the third insulating film is formed with a deposited film.

9. The non-volatile semiconductor storage device according to claim 8,
wherein the first insulating film and the second insulating film are thermal oxide films, and the third insulating film is an oxide film.

10. The non-volatile semiconductor storage device according to claim 8,
wherein the first insulating film is a thermal oxide film, the second insulating film is an oxynitride film formed by thermal oxidation, and the third insulating film is an oxynitride film.

11. A method for producing a non-volatile semiconductor storage device comprising:
a first step of forming a gate insulating film and a gate electrode sequentially on a semiconductor substrate;
a second step of forming a side wall on a side face of the control gate electrode and then etching the semiconductor substrate using the formed side wall as a mask, thereby forming a first region on which the side wall is located, a second region obtained by etching the first region, and a step portion connecting the first region and the second region such that an angle formed between a side face of the step portion and an upper surface of the second region becomes an obtuse angle;
a third step of removing the side wall and then forming an insulating film over the side face of the control gate electrode on the side of the step portion, the first region, the step portion and the second region; and
a fourth step of forming a floating gate electrode on the side face of the control gate electrode on the side of the step portion and the second region including the step portion on the insulating film in a self-alignment manner.

12. The method for producing a non-volatile semiconductor storage device according to claim 11,
wherein in the second step, the step portion and the second region are formed by isotropic dry etching.

13. The method for producing a non-volatile semiconductor storage device according to claim 11,
wherein in the second step, the step portion and the second region are formed by wet etching.

14. The method for producing a non-volatile semiconductor storage device according to claim 11,
wherein in the second step, the step portion and the second region are formed by dry etching and wet etching.

15. The method for producing a non-volatile semiconductor storage device according to claim 11,
wherein in the second step, an angle formed between a side face of the step portion and an upper surface of the second region is about 100° or more.

16. The method for producing a non-volatile semiconductor storage device according to claim 11,
wherein in the second step, an angle formed between a side face of the step portion and an upper surface of the second region is about 110° or more and about 130° or less.

17. A method for producing a non-volatile semiconductor storage device comprising:
a first step of forming a gate insulating film and a gate electrode sequentially on a semiconductor substrate;
a second step of forming a side wall on a side face of the control gate electrode and then etching the semiconductor substrate using the formed side wall as a mask, thereby forming a first region on which the side wall is located, a second region obtained by etching the first region, and a step portion connecting the first region and the second region;
a third step of removing the side wall and then forming a first insulating film over the side face of the control gate electrode on the side of the step portion, the first region, the step portion and the second region by deposition;
a fourth step of forming a second insulating film at the interface between the first insulating film and the side face of the control gate electrode on the side of the step portion, the first region, the step portion and the second region by thermal oxidation; and
a fifth step of forming a floating gate electrode on the side face of the control gate electrode on the side of the step portion and the second region including the step portion on the first insulating film in a self-alignment manner.

18. The method for producing a non-volatile semiconductor storage device according to claim 17,
wherein in the third step, the first insulating film is an oxynitride film.

19. The method for producing a non-volatile semiconductor storage device according to claim 17,
wherein in the fourth step, the second insulating film is formed in an ambient containing nitrogen.

20. The method for producing a non-volatile semiconductor storage device according to claim 17, further comprising a step of performing an annealing treatment in a non-oxidative ambient with respect to the first insulating film and the second insulating film between the fourth step and the fifth step.

21. A method for producing a non-volatile semiconductor storage device comprising:
a first step of forming a gate insulating film and a gate electrode sequentially on a semiconductor substrate;
a second step of forming a side wall on a side face of the control gate electrode and then etching the semiconductor substrate using the formed side wall as a mask, thereby forming a first region on which the side wall is located, a second region obtained by etching the first region, and a step portion connecting the first region and the second region;
a third step of removing the side wall and then forming a first insulating film over the side face of the control gate electrode on the side of the step portion, the first region, the step portion and the second region by thermal oxidation;
a fourth step of forming a second insulating film on the first insulating film by deposition;
a fifth step of forming a third insulating film at an interface between the first insulating film and the side face of the control gate electrode on the side of the step portion, the first region, the step portion and the second region by thermal oxidation; and
a sixth step of forming a floating gate electrode on the side face of the control gate electrode on the side of the step portion and the second region including the step portion on the second insulating film in a self-alignment manner.

22. The method for producing a non-volatile semiconductor storage device according to claim 21,
wherein in the fourth step, the second insulating film is an oxynitride film.

23. The method for producing a non-volatile semiconductor storage device according to claim 21,
wherein in the fifth step, the third insulating film is formed in an ambient containing nitrogen.

24. The method for producing a non-volatile semiconductor storage device according to claim 21, further comprising a step of performing an annealing treatment in a non-oxidative ambient with respect to the first insulating film, the second insulating film and the third insulating film between the fifth step and the sixth step.
